(19) United States
(12) Patent Application Publication
(10) Pub. No.: US 2004/0124932 A1
(43) Pub. Date: Jul. 1, 2004

(54) Voltage control oscillator capable of adjusting a frequency and method thereof

(75) Inventor: Chao-Hsin Lu, Da-Yuan Shiang (TW)

Correspondence Address: BACON & THOMAS, PLLC, 625 SLATERS LANE, FOURTH FLOOR, ALEXANDRIA, VA, 22314

(73) Assignee: Realtek Semiconductor Corp., Hsinchu (TW)

(21) Appl. No.: 10/734,287

(22) Filed: Dec. 15, 2003

(30) Foreign Application Priority Data
Dec. 31, 2002 (TW) 091138144

(51) Int. Cl. H03B 1/00

(52) U.S. Cl. 331/57

(57) ABSTRACT

A voltage control oscillating apparatus capable of automatically adjusting a oscillating frequency, comprising: a plurality of serial-coupled voltage control delay lines (VCDL) for outputting a plurality of oscillating signals respectively according to a voltage control signal, each of the oscillating signals is corresponding to a oscillating frequency; a multiplexer coupled to the VCDL for selecting one of the oscillating signals to be an output oscillating signal according to a control signal; a frequency detector coupled to the multiplexer for outputting a detecting signal according to the output oscillating signal; and a controller coupled to the frequency detector for outputting the control signal to the multiplexer according to the detecting signal.

### BACKGROUND OF THE INVENTION

1. Field of the Invention

The present invention relates to a voltage control oscillator and, more particularly, to a voltage control oscillator capable of adjusting a frequency curve and method thereof.

2. Description of Related Art

A typical phase locked loop (PLL) system generally uses a voltage-controlled oscillator (VCO) to produce required frequencies. As shown in FIG. 1A, the VCO 10 includes a series of n-stage voltage control delay lines (VCDL), each stage having a control terminal, an output terminal, and an input terminal. Take the i-th stage VCDL as an example, the i-th stage VCDL has a control terminal coupled to a common voltage control signal Vc for outputting an oscillating signal to an input terminal of the (i+1)th stage VCDL in a delay time Ti(Vc). An output terminal of the n-th stage VCDL is coupled to an input terminal of the first stage VCDL and outputs an oscillating signal with a central frequency

$$\frac{1}{2 \times {\sum }_{k = 1}^{n} Tk ( Vc )} .$$

It is noted that each stage VCDL has a specific delay time represented by a function of voltage control signal Vc.

FIG. 1B illustrates frequency-voltage characteristic curves of the VCO 10. It is well-known to those skilled in the art that the frequency-voltage characteristic curve of the practical VCO device may be varied due to the process variation. For example, as shown in FIG. 1B, if the curve A represents the frequency-voltage characteristic curve of a voltage-controlled oscillators (VCOs) 10. The frequency-voltage characteristic curve possibly shifts to a higher frequency as a curve B or a lower frequency as a curve C for the other VCOs. If the shift of the frequency-voltage curve exceeds a certain value, the operation of the VCOs cannot meet the desired specification of an integrated circuit. However, the variation of IC manufacturing processes cannot be prevented. Thus the yield of the VCOs manufacturing processes may be limited and The VCOs device may work abnormally or even be failed due to, for example, the change of voltage controlled oscillating frequency.

### SUMMARY OF THE INVENTION

The object of the present invention is to provide a voltage control oscillating apparatus and method capable of automatically adjusting a frequency-voltage curve, which can compensate the shift of the voltage control oscillating frequency due to the reasons such as the variation of IC manufacturing processes.

According to the object of the invention, the present invention provides a voltage control oscillating apparatus capable of automatically adjusting a oscillating frequency, comprising: a plurality of serial-coupled voltage control delay lines (VCDL) for outputting a plurality of oscillating signals respectively according to a voltage control signal, each of the oscillating signals is corresponding to a oscillating frequency; a multiplexer coupled to the VCDL for selecting one of the oscillating signals to be an output oscillating signal according to a control signal; a frequency detector coupled to the multiplexer for outputting a detecting signal according to the output oscillating signal; and a controller coupled to the frequency detector for outputting the control signal to the multiplexer according to the detecting signal.

According to the object of the invention, the present invention also provides a method for used in a voltage control oscillating apparatus for automatically adjusting a oscillating frequency comprising the steps of: detecting the oscillating frequency through detecting an output oscillating signal; and selecting one of a plurality of oscillating signals according to the result of the detection, wherein each of the oscillating signals is corresponding to a oscillating frequency.

Other objects, advantages, and novel features of the invention will become more apparent from the following detailed description when taken in conjunction with the accompanying drawings.

### BRIEF DESCRIPTION OF THE DRAWINGS

FIG. 1A is a schematic diagram of a conventional voltage control oscillating apparatus;

FIG. 1B is a graph of frequency-voltage characteristic curves of VCOs; and

FIG. 2 is a schematic diagram of a voltage control oscillating apparatus capable of automatically adjusting a frequency curve according to the embodiment of the present invention.

### DETAILED DESCRIPTION OF THE PREFERRED EMBODIMENT

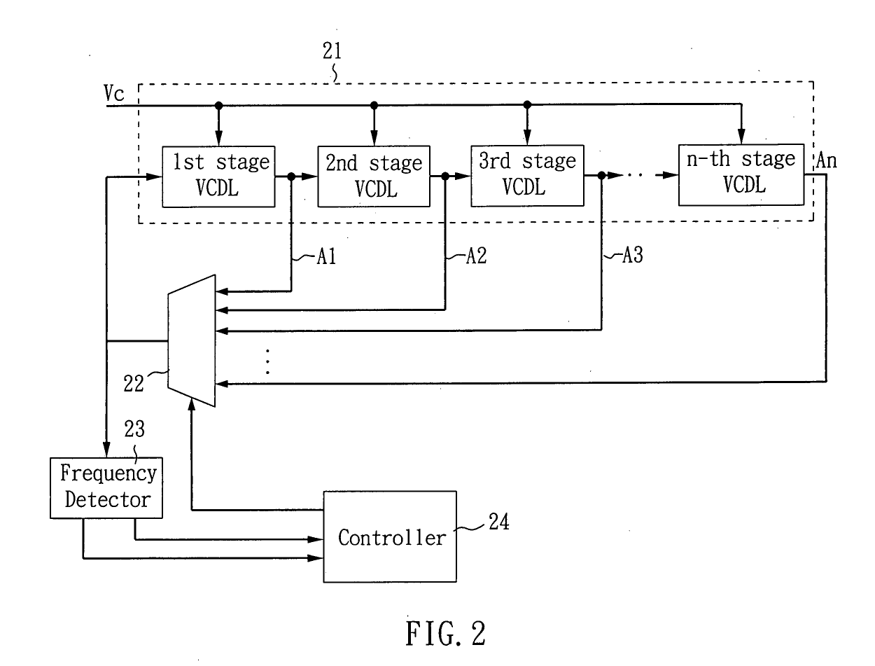

FIG. 2 is a schematic diagram of a voltage control oscillating apparatus capable of automatically adjusting a frequency curve in accordance with the embodiment of the present invention. The voltage-controlled oscillator (VCO) includes n-stage voltage control delay lines (VCDL) 21, a multiplexer 22, a frequency detector 23, and a controller 24. Each stage of n-stage voltage control delay lines (VCDL) 21 having a control terminal coupled to a common voltage control signal Vc. The delay time Ti(Vc) of each stage is dependent on the common voltage control signal Vc. The voltage control delay line of each stage has an output terminal for outputting an output signal Ai coupled to an input terminal of the voltage control delay line of the next stage.

The multiplexer 22 has n input terminals coupled to the output terminals of the n-stage voltage control delay line respectively. Also, the multiplexer 22 has an output terminal coupled to an input terminal of the first stage voltage control delay line to form an oscillation loop.

The frequency detector 23 has an input terminal coupled to the output terminal of the multiplexer 22, which detects a signal frequency output of the multiplexer 22 and produces an output based on the signal frequency output of the multiplexer 22. The controller 24 adjusts the signal frequency output of the multiplexer 22 according to the output of the frequency detector 23.

The VCO of the embodiment of the present invention has a central oscillating frequency

$$\frac{1}{2 \times {\sum }_{k = 1}^{i} Tk ( Vc )} ,$$

which the maximum central oscillating frequency is

$$\frac{1}{2 \times {\sum }_{k = 1}^{n} Tk ( Vc )}$$

and the minimum central oscillating frequency is

$$\frac{1}{2 \times T1 ( Vc )} .$$

The selection performed by the multiplexer 22 to select one of the signals outputted from the n-stage voltage control delay line 21 as the output signal of the multiplexer 22 corresponds to the central oscillating frequency of the VCO. The selection of the multiplexer 22 is controlled by the controller 24 based on the result of the frequency detection performed by the frequency detector 23.

For example, if a central oscillating frequency (f) required by the voltage control oscillating apparatus is

$$\frac{1}{2 \times {\sum }_{k = 1}^{6} Tk ( Vc )} ,$$

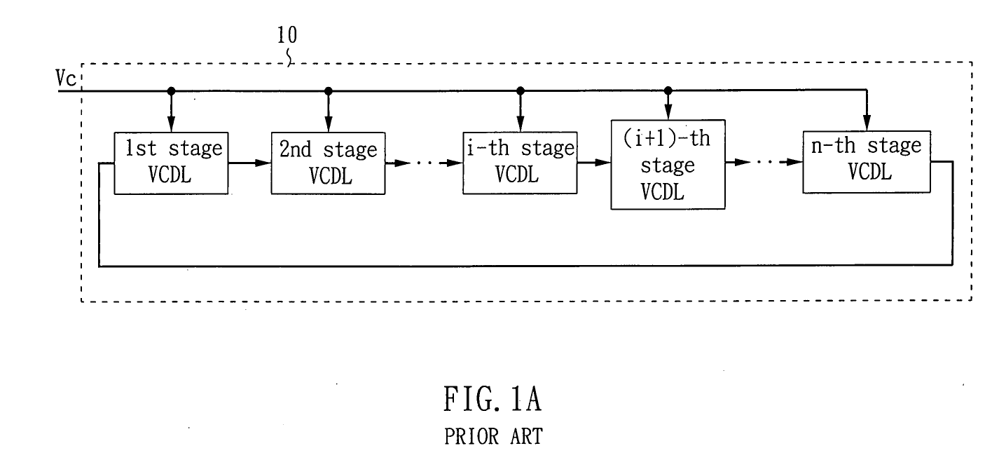

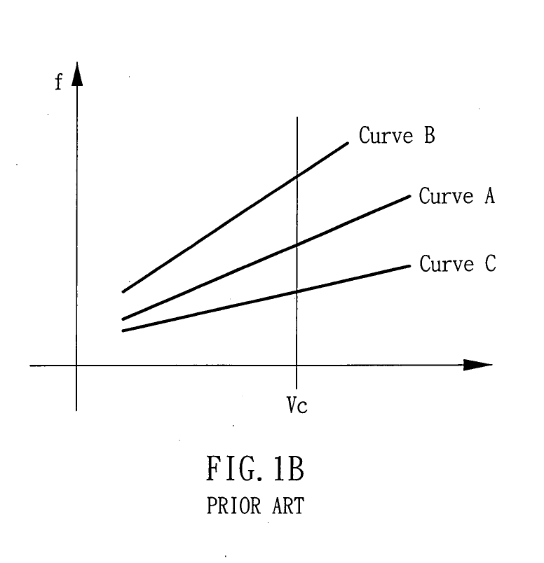

as shown to be curve A of FIG. 1B, the multiplexer 22 selects the signal A6 outputted from the sixth stage of voltage control delay line 21 as the output signal. However, if the practical central oscillating frequency (f) is curve B, not curve A, as shown in FIG. 1B, due to various reasons such as the variation of IC manufacturing process, it can be detected by the frequency detector 23. The frequency detector 23 outputs a prolonging path signal to the controller 24 based on the result of the frequency detection. The controller 24 selects the signal outputted from the next stage voltage control delay line, such as an output signal A7 of the seventh voltage control delay line, to be the output signal of the multiplexer 22. In this manner, a longer oscillation loop is formed and an oscillating signal corresponding to a lower central frequency is outputted. That is, the central oscillation frequency can be shifted from a higher frequency, such as curve B, toward a desired lower frequency, such as curve A.

If the practical central oscillating frequency (f) is curve C, not curve. A, as shown in FIG. 1B, due to various reasons such as the variation of IC manufacturing process, it can be detected by the frequency detector 23. The frequency detector 23 outputs a shorten path signal to the controller 24 based on the result of the frequency detection. The controller 24 selects the signal outputted from the previous stage voltage control delay line, such as an output signal A5 of the fifth voltage control delay line, to be the output signal of the multiplexer 22. In this manner, a shorter oscillation loop is formed and an oscillating signal corresponding to a higher central frequency is outputted. That is, the central oscillation frequency can be shifted from a lower frequency, such as curve C, toward a desired higher frequency, such as curve A.

Although the present invention has been explained in relation to its preferred embodiment, it is to be understood that many other possible modifications and variations can be made without departing from the spirit and scope of the invention as hereinafter claimed.

What is claimed is:

1. A voltage control oscillating apparatus capable of adjusting a frequency of an output oscillating signal of the voltage control oscillating apparatus, comprising:
a plurality of serial-coupled voltage control delay lines (VCDL) for outputting a plurality of oscillating signals respectively according to a voltage control signal, each of the oscillating signals is corresponding to an oscillating frequency;
a multiplexer coupled to the VCDL for selecting one of the oscillating signals to be the output oscillating signal according to a control signal;
a frequency detector coupled to the multiplexer for outputting a detecting signal according to the output oscillating signal; and
a controller coupled to the frequency detector for outputting the control signal to the multiplexer according to the detecting signal.

2. The voltage control oscillating apparatus of claim 1, wherein each of the voltage control delay lines includes a control terminal for receiving the voltage control signal, an input terminal coupled to the previous voltage control delay line, and an output terminal coupled to the next voltage control delay line and the multiplexer for outputting the corresponding oscillating signal.

3. A method for used in a voltage control oscillating apparatus for adjusting a frequency of an output oscillating signal, the method comprising the steps of:
detecting the frequency of the output oscillating signal; and
selecting one of a plurality of oscillating signals as the output oscillating signal according to the result of the detection, wherein each of the oscillating signals is corresponding to an oscillating frequency.

4. The method of claim 3, wherein the method further comprises generating a control signal according to the result of the detection for selecting one of the oscillating signals.
